(19) United States
(12) Patent Application Publication
(10) Pub. No.: US 2025/0323047 A1
(43) Pub. Date: Oct. 16, 2025

(54) WAFER STRESS RELIEF STRUCTURE AND METHOD FOR MANUFACTURING THE SAME

(71) Applicant: POTENS SEMICONDUCTOR CORP., Zhubei City (TW)

(72) Inventors: Tung Ming LAI, Zhubei City (TW); Hao Hsuan LO, Zhubei City (TW)

(21) Appl. No.: 18/894,614

(22) Filed: Sep. 24, 2024

(30) Foreign Application Priority Data
Apr. 15, 2024 (TW) 113114039

(51) Int. Cl. H01L 21/304; H01L 23/00

(52) U.S. Cl. CPC H01L 21/304; H01L 23/562

(57) ABSTRACT

A wafer stress relief structure and a method for manufacturing the same are provided. The method mainly involves performing a secondary grinding on a wafer after backside grinding to reduce a thickness of the wafer. The secondary grinding forms one or a plurality of trenches locally on a surface opposite to an epitaxial surface of the wafer, to balance and relieve stress accumulated in the wafer during a thinning process, thereby improving wafer warpage.

### CROSS-REFERENCE TO RELATED APPLICATIONS

The present disclosure claims priority to a Taiwan Patent Application No. 113114039 filed on Apr. 15, 2024, the disclosures of which are incorporated in their entirety by reference herein.

### BACKGROUND OF THE DISCLOSURE

### Field of the Disclosure

The present disclosure particularly relates to a wafer stress relief structure and a method for manufacturing the same, in which a plurality of trenches are formed on a backside of a wafer through secondary grinding to reduce wafer warpage.

### Brief Description of Related Art

In an existing integrated circuit (IC) manufacturing process, particularly a trench metal oxide semiconductor field effect transistor (MOSFET) manufacturing process, a frontside of a wafer has high-density and deep trenches. During a back grinding process, as a grinding amount increases, a thickness of the wafer decreases. Structurally, a backside of the wafer is relatively flat compared to the frontside with the trenches. Thus, structural stress and mechanical stress accumulate. This situation causes the wafer to warp easily due to uneven stress when a protective tape is removed. This wafer warpage increases difficulty of subsequent manufacturing process operations such as backside gold plating, wafer testing, and packaging processing, and also increases a risk of wafer breakage and scrapping, seriously affecting a yield of the IC manufacturing process.

Various methods for improving wafer warpage have been disclosed in the prior art. For example, a TAIKO process (see Taiwan Patent Application Publication No. 201301376A1) uses a specialized grinding device to thin a wafer while maintaining a certain thickness at a wafer edge to increase wafer strength and reduce warpage. Another prior art technology employs an etching process (see Chinese Patent Application Publication No. 113053733A) or a photolithography process (see U.S. Patent Application Publication No. 2017011329A1) to form a plurality of trenches on a backside of a wafer to balance stress of the wafer. However, application of these methods for reducing warpage, whether through the more precise grinding device of the former or the etching or photolithography process of the latter, has a problem of significantly increasing manufacturing cost.

### SUMMARY OF THE DISCLOSURE

The main object of the present disclosure is to provide a technology using secondary grinding to form a plurality of second trenches on a backside of a wafer. These second trenches balance accumulated stress inside the wafer, thereby achieving an effect of reducing wafer warpage while simultaneously offering an advantage of saving manufacturing cost.

In order to achieve the aforementioned object, a wafer stress relief structure and a method for manufacturing the same are provided in the present disclosure. The manufacturing method includes the following operations: First, a protective layer is attached to a frontside of a wafer formed with a plurality of first trenches to cover a surface of the wafer. A grinding device is used to grind a backside of the wafer to achieve a desired thickness. Subsequently, the grinding device is used to perform a local grinding on the backside of the wafer, so that the backside of the wafer is formed with a plurality of second trenches. Furthermore, the second trenches are formed relative to the first trenches on the frontside, for example relatively parallel, perpendicular, or at a specified angle, to balance or relieve stress accumulated by the first trenches on the frontside during a manufacturing process. Additionally, the grinding device used to perform the second grinding is same as that used to perform the first grinding, thereby further achieving reducing wafer warpage, effectively saving cost, and improving a yield of the manufacturing process with existing equipment.

### BRIEF DESCRIPTION OF THE DRAWINGS

FIG. 1 is a flowchart (1) of a method according to the present disclosure.

FIG. 2 is an implementation schematic diagram (1) according to the present disclosure.

FIG. 3 is an implementation schematic diagram (2) according to the present disclosure.

FIG. 4 is an implementation schematic diagram (3) according to the present disclosure.

FIG. 5 is an implementation schematic diagram (4) according to the present disclosure.

FIG. 6 is an implementation schematic diagram (5) according to the present disclosure.

FIG. 7 is a schematic diagram illustrating an embodiment (1) according to the present disclosure.

FIG. 8 is a schematic diagram illustrating an embodiment (2) according to the present disclosure.

FIG. 9 is a schematic diagram illustrating an embodiment (3) according to the present disclosure.

FIG. 10 is a flowchart (2) of a method according to the present disclosure.

FIG. 11 is an implementation schematic diagram (6) according to the present disclosure.

### DETAILED DESCRIPTION OF PREFERRED EMBODIMENTS

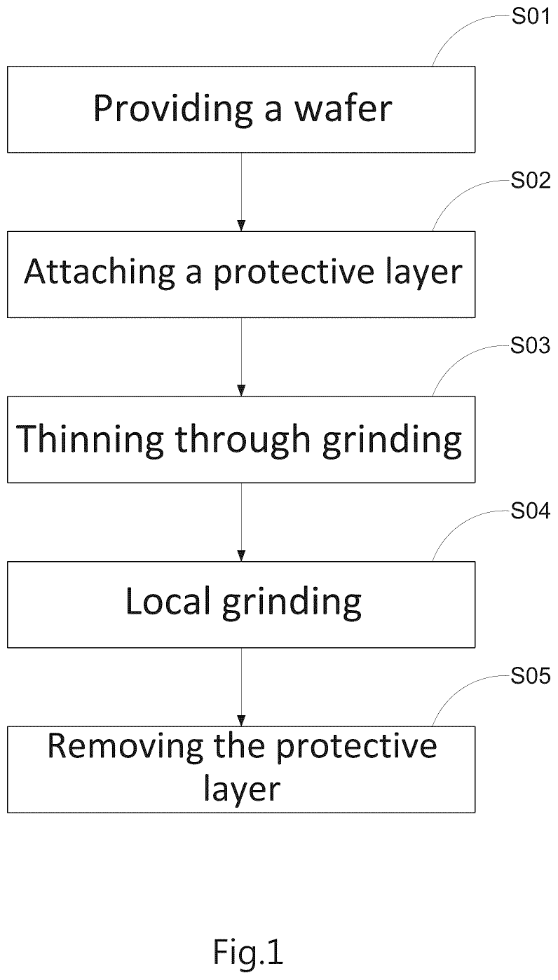

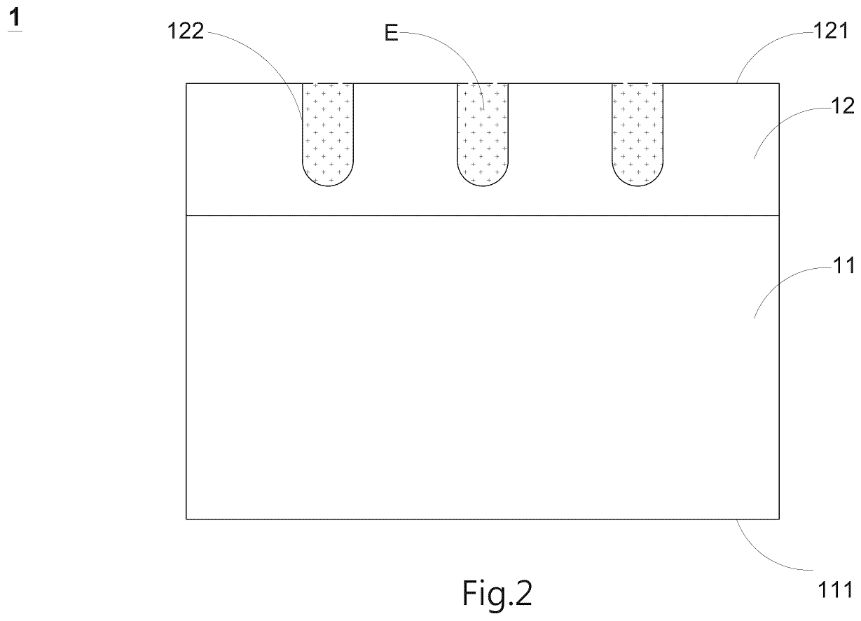

Referring to FIGS. 1 and 2, the manufacturing method according to the present disclosure includes the following operations:

A wafer providing operation S01: Firstly, a wafer 1 is provided. The wafer 1 may be composed of a substrate 11 and an epitaxial layer 12 crystallized upward. The wafer 1 has a first surface 121, which is an upper surface of the epitaxial layer 12, and a second surface 111, which is a lower surface of the substrate 11. The first surface 121 is formed with a plurality of first trenches 122, each of which typically has a U-shaped structure that is helpful to reduce ON resistance (R_{DS(on)}). The first trenches 122 have been processed to form a plurality of semiconductor elements E.

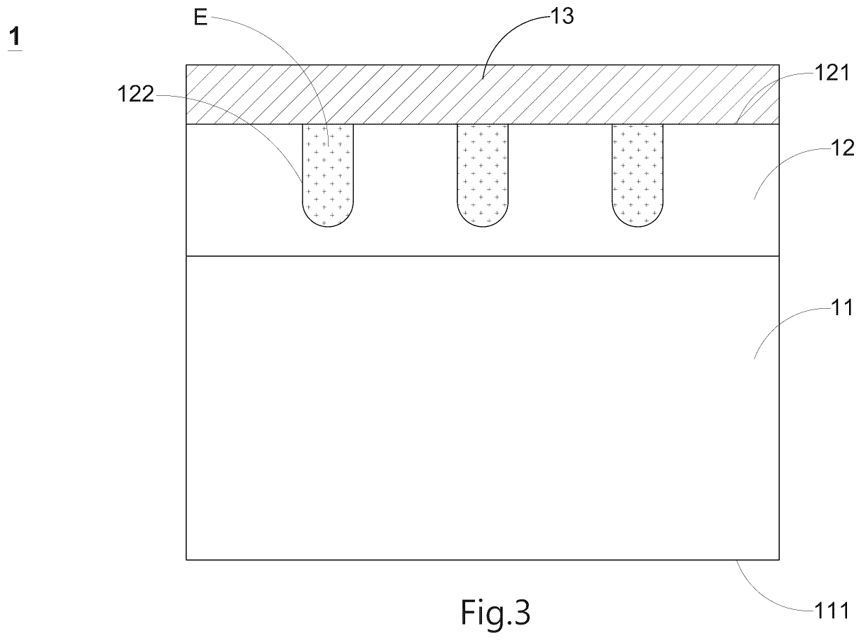

A protective layer attaching operation S02: Referring to FIG. 3, a protective layer 13 is attached to the epitaxial layer 12 of the wafer 1. For example, a grind tape can be adhered to the epitaxial layer 12, or a grinding glass sheet can be attached to the epitaxial layer 12 using electrostatics. In this way, the first surface 121 can be completely covered, thereby protecting the first surface 121 and the filled semiconductor elements E from contamination and damage during a subsequent manufacturing process.

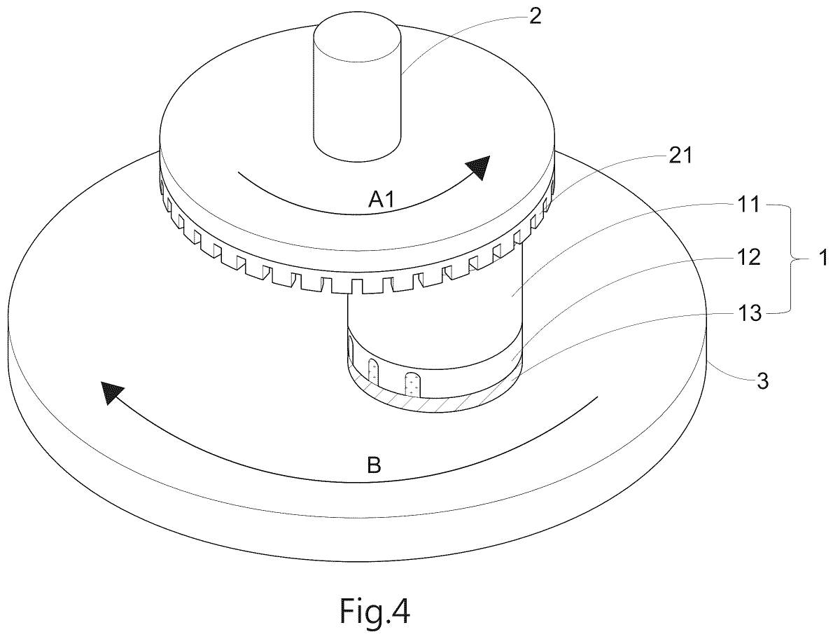

A thinning through grinding operation S03: Referring to FIG. 4, the wafer 1 is placed on a rotating base 3 with the first surface 121 facing downward and the second surface 111 facing upward. A grinding wheel 21, assembled at a bottom of the grinding device 2, is brought into contact with the second surface 111 of the wafer 1 to perform a conventional thinning through grinding on the wafer 1. During the thinning through grinding, around a center axis of the grinding device 2, the grinding device 2 rotates in a grinding direction A1, and the rotating base 3 rotates in a rotation direction B opposite to the grinding direction A1 (in the present embodiment, the grinding direction A1 is counterclockwise and the rotation direction B is clockwise). This causes the grinding wheel 21 to grind the second surface 111, reducing a thickness of the wafer 1 to a desired first thinned thickness.

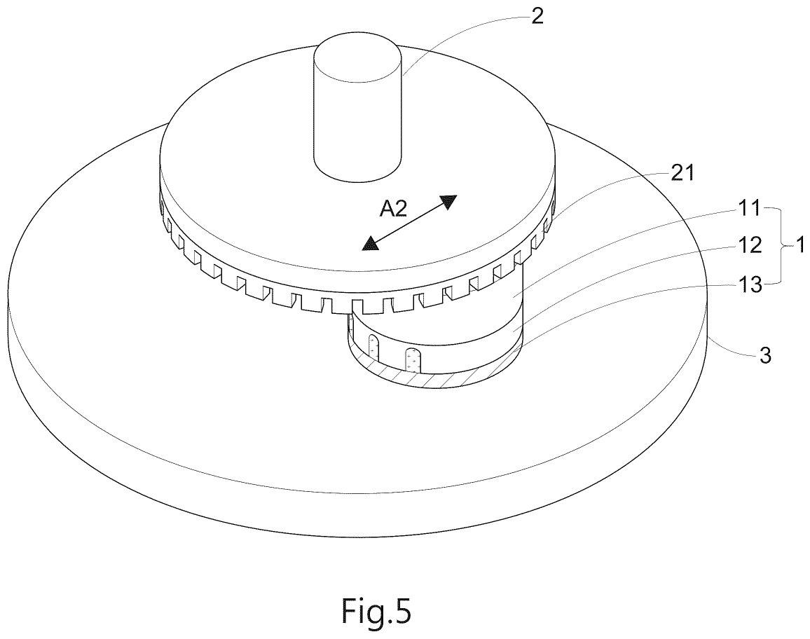

A local grinding operation S04: Referring to FIG. 5, similarly, the wafer 1 is placed on the rotating base 3 with the first surface 121 facing downward and the second surface 111 facing upward. The same grinding device 2 used in the thinning through grinding operation S03 is employed to perform a local thinning on the wafer 1. During the local thinning, the rotating base 3 is fixed in a stationary state. A changed grinding direction A2 of the grinding device 2 causes the grinding device 2 to grind a part of the second surface 111 in a direction that is parallel (perpendicular, or at a specified angle) to directions of the first trenches 122. In this way, the wafer 1 is locally thinned to a second thinned thickness while a part of the wafer 1 that is not locally ground remains at the first thinned thickness.

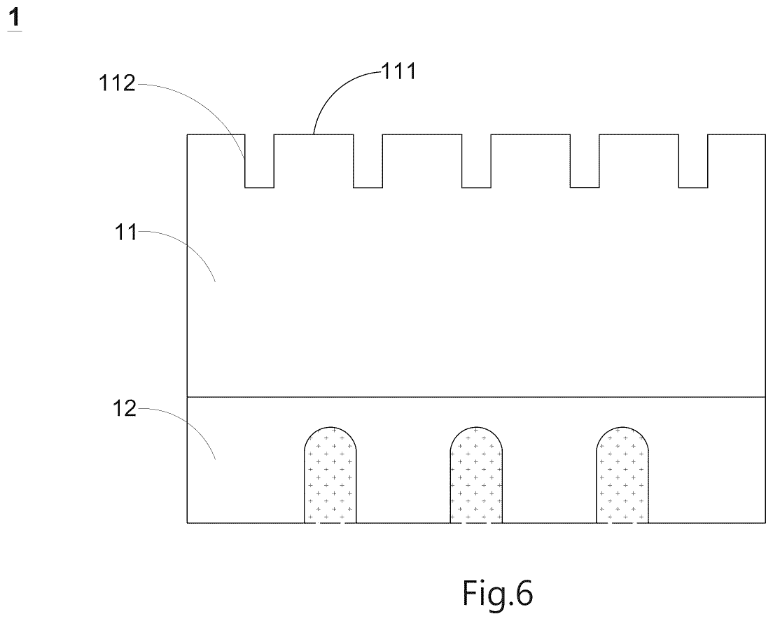

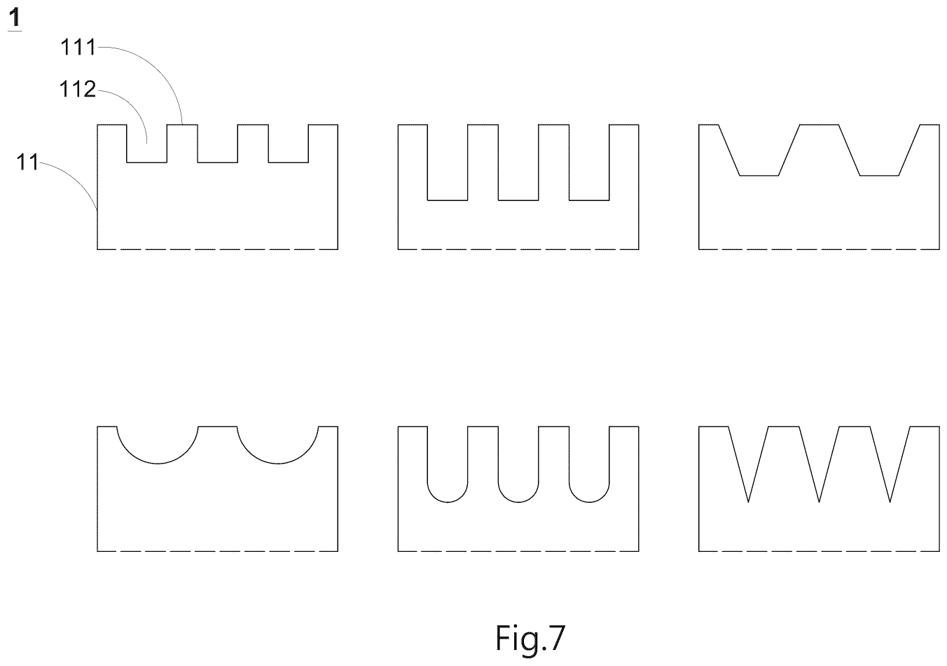

A protective layer removal operation S05: Referring to FIG. 6, upon completion of the local thinning, the second surface 111 of the wafer 1 is formed with a plurality of second trenches 112. Referring to FIG. 7, each of the second trenches 112 on the second surface 111 of the wafer 1 can optionally be formed into different shapes by grinding, according to the first trenches 122 on the first surface 121 or accumulated stress. For example, each of the second trenches is in one of the following shapes or a combination thereof: square, trapezoidal, arc-shaped, U-shaped, and V-shaped. But the present disclosure is not limited thereto. After removing the protective layer 13, a thinned wafer 1 with reduced warpage is obtained for subsequent manufacturing process operations.

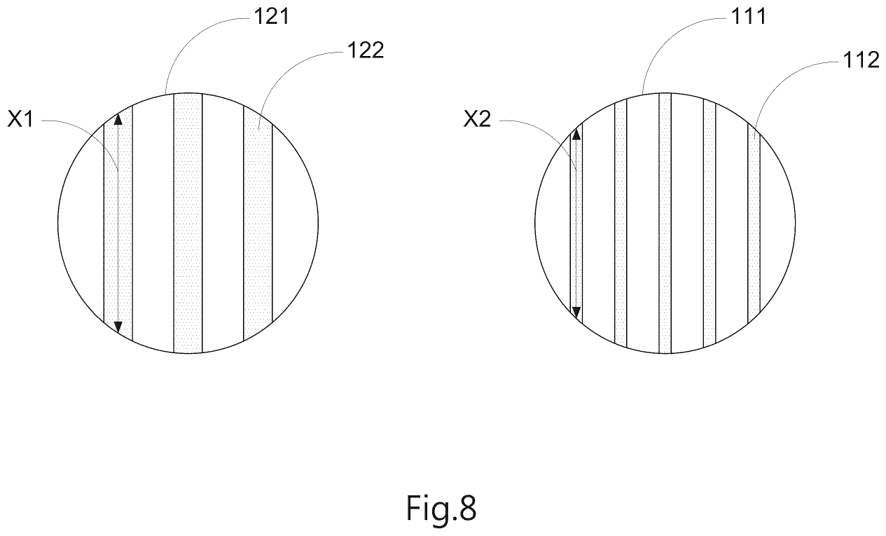

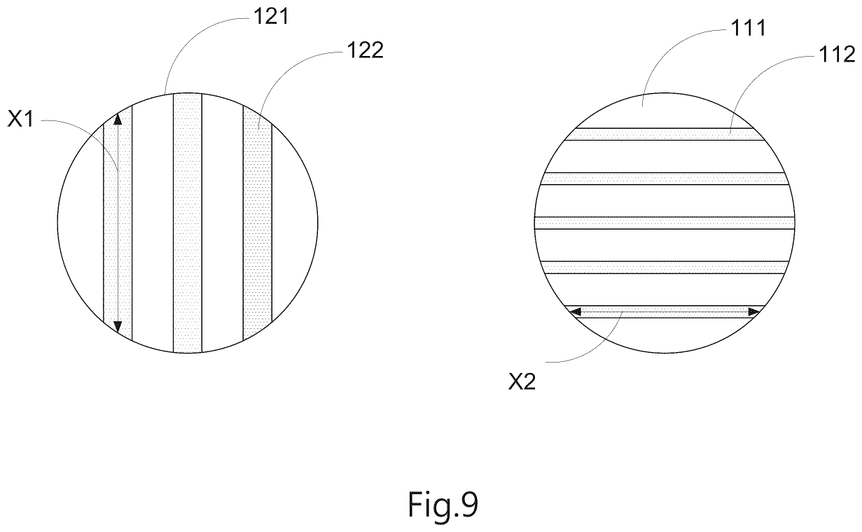

Referring to FIG. 8, upon performing the local grinding on the wafer 1, the following is observed: The first trenches 122 on the first surface 121 are formed in a plurality of corresponding first directions X1, respectively. The second trenches 112 on the second surface 111 are formed in a plurality of corresponding second directions X2, respectively. In the present embodiment, the second directions X2 are parallel to the first directions X1. Referring to FIG. 9, in the present embodiment, the second directions X2 are perpendicular to the first directions X1. Upon implementation of the aforementioned embodiments, the second trenches 112 on the second surface 111 form a special pattern (the second trenches 112 on the second surface 111 are parallel, perpendicular, or at a specified angle to the first trenches 122 on the first surface 121), thereby relieving stress accumulated in the wafer 1, and reducing warpage of the wafer 1.

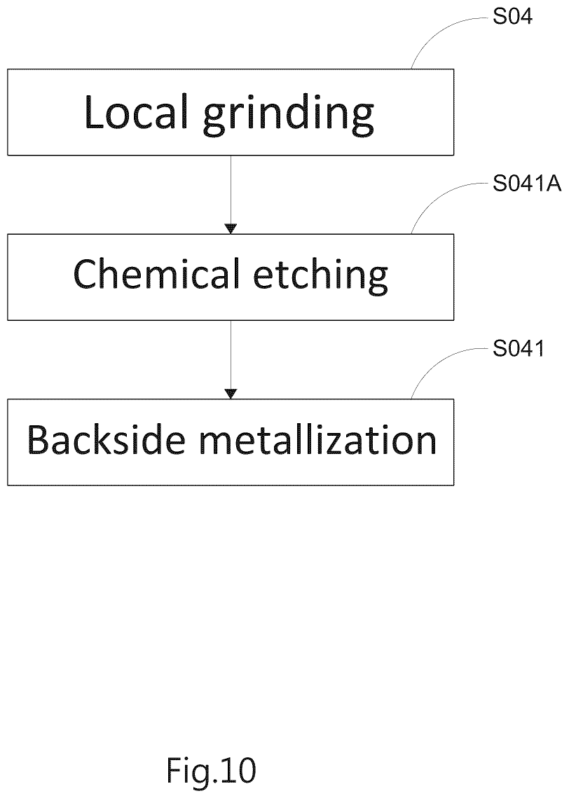

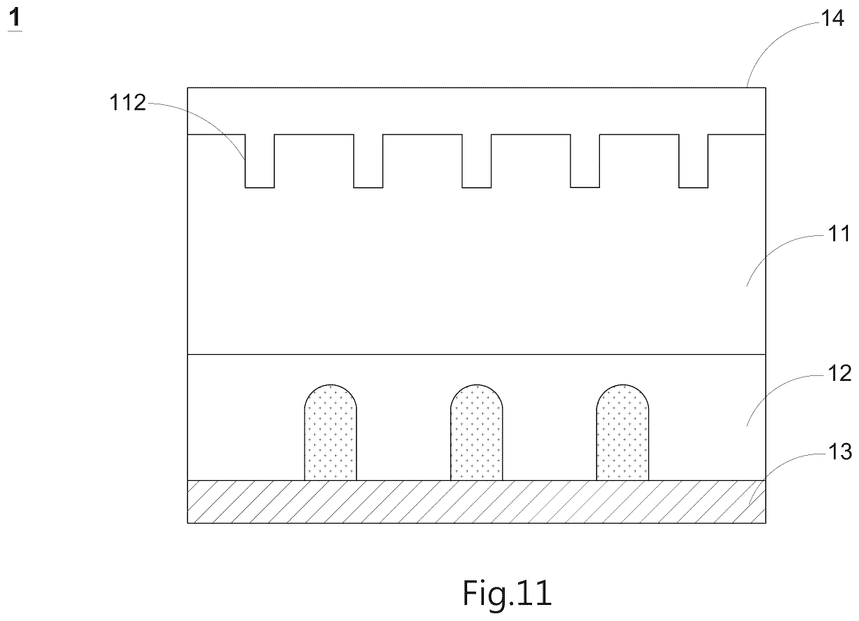

Referring to FIGS. 10 and 11, after the local grinding operation S04, a backside metallization operation S041 can be further performed. This operation involves a metallization process which can be, for example, one of the following or a combination thereof: sputtering or deposition. Through the metallization process, metal or metal alloy is deposited in the second trenches 112. The metal or metal alloy can be, for example, one of the following or a combination thereof: titanium (Ti), nickel (Ni), silver (Ag), gold-tin alloy (Au/Sn), or gold-zinc alloy (Au/Zn). But the present disclosure is not limited thereto. In this way, a metal layer 14 is formed on the second surface 111, so that the wafer 1 has reduced contact surface impedance, good thermal conductivity, and increased mechanical strength. Thus, warpage of the wafer 1 is improved. Additionally, during grinding processes (in the thinning through grinding operation S03 and the local grinding operation S04), a damage layer is formed on the surface (the second surface 111) of the epitaxial layer 12, leading to issues such as accumulation of residual stress. Therefore, before the backside metallization operation S041, a chemical etching process S041A can be performed to remove the damage layer and the resultant residual stress.

As described above, the present disclosure mainly uses the existing grinding device, with the grinding direction adjusted, to perform the local grinding on the backside of the wafer. In this way, the second trenches are formed on the backside of the wafer. The directions of the second trenches are either parallel or perpendicular to the directions of the first trenches on the frontside of the wafer, thereby relieving the accumulated internal stress. Accordingly, it is evident that the present disclosure, upon implementation, can indeed achieve an object of providing a technology using secondary grinding to form a plurality of second trenches on a backside of a wafer. These second trenches balance accumulated stress inside the wafer, thereby achieving an effect of reducing wafer warpage while simultaneously offering an advantage of saving manufacturing cost.

The above is only the preferred embodiments of the present disclosure, and is not intended to limit the present disclosure to the forms disclosed. Any modifications, equivalent alternatives, and improvements made within the spirit and the scope of present disclosure by persons skilled in the art should be included in the scope of claims of the present disclosure.

Reference numerals in Drawings

| | |
|---|---|
| S01 | a wafer providing operation |
| S02 | a protective layer attaching operation |
| S03 | a thinning through grinding operation |
| S04 | a local grinding operation |
| S05 | a protective layer removal operation |
| S041 | a backside metallization operation |
| S041A | a chemical etching process |
| 1 | a wafer |
| 11 | a substrate |
| 12 | an epitaxial layer |
| 111 | a second surface |
| 121 | a first surface |
| 112 | a plurality of second trenches |
| 122 | a plurality of first trenches |
| 13 | a protective layer |
| 14 | a metal layer |
| 2 | a grinding device |
| 3 | a rotating base |
| 21 | a grinding wheel |
| E | a plurality of semiconductor elements |
| A1 | a grinding direction |
| A2 | a grinding direction |
| B | a rotation direction |
| X1 | a plurality of first directions |
| X2 | a plurality of second directions |

What is claimed is:

1. A method for manufacturing a wafer stress relief structure, wherein the method comprises:
a wafer providing operation for providing a wafer, wherein the wafer has a first surface and a second surface opposite to the first surface, wherein the first surface is formed with a plurality of first trenches;
a protective layer attaching operation for attaching a protective layer to the first surface of the wafer;
a thinning through grinding operation for providing a grinding device to grind the second surface of the wafer to reduce a thickness of the wafer; and
a local thinning operation for performing, by the grinding device, a local grinding on the second surface so that the second surface is formed with a plurality of second trenches.

2. The method for manufacturing the wafer stress relief structure of claim 1, wherein, after the local thinning operation, a protective layer removal operation is performed to remove the protective layer attached to the wafer.

3. The method for manufacturing the wafer stress relief structure of claim 1, wherein the local grinding comprises placing the wafer on a rotating base in a stationary state, and then causing the grinding device to contact the second surface and grind in a direction that is relatively parallel, perpendicular, or at a specified angle to the first trenches to form the second trenches.

4. The method for manufacturing the wafer stress relief structure of claim 1, wherein the first trenches on the first surface are formed in a plurality of first directions, respectively, the second trenches on the second surface are formed in a plurality of second directions, respectively, and the second directions are parallel, perpendicular, or at a specified angle to the first directions.

5. The method for manufacturing the wafer stress relief structure of claim 1, wherein each of the second trenches is in one of the following shapes or a combination thereof: square, rectangular, trapezoidal, arc-shaped, U-shaped, and V-shaped.

6. The method for manufacturing the method for manufacturing the wafer stress relief structure of claim 1, wherein, after the local thinning operation, a backside metallization operation is performed to perform a metallization process on the second surface to form a metal layer on the second surface.

7. The method for manufacturing the wafer stress relief structure of claim 6, wherein, before performing the metallization process on the second surface, a chemical etching process is performed to remove a damage layer formed on the second surface.

8. The method for manufacturing the wafer stress relief structure of claim 6, wherein the metallization process is one of sputtering or deposition.

9. The method for manufacturing the wafer stress relief structure of claim 6, wherein the metal layer is one of the following or a combination thereof: titanium (Ti), nickel (Ni), silver (Ag), gold-tin alloy (Au/Sn), or gold-zinc alloy (Au/Zn).

10. A wafer stress relief structure, comprising:
a wafer having a first surface and a second surface opposite to the first surface, wherein the first surface is formed with a plurality of first trenches, and the second surface is formed with a plurality of second trenches;
wherein the first trenches on the first surface are formed in a plurality of first directions, respectively, the second trenches on the second surface are formed in a plurality of second directions, respectively, and the second directions are parallel, perpendicular, or at a specified angle to the corresponding first directions, so that the second trenches balance and relieve stress accumulated in the wafer during a thinning process.

11. The wafer stress relief structure of claim 10, wherein each of the second trenches is in one of the following shapes or a combination thereof: square, trapezoidal, arc-shaped, U-shaped, and V-shaped.

12. The wafer stress relief structure of claim 10, wherein a metal layer is formed on the second surface.

13. The wafer stress relief structure of claim 12, wherein the metal layer is one of the following or a combination thereof: titanium (Ti), nickel (Ni), silver (Ag), gold-tin alloy (Au/Sn), or gold-zinc alloy (Au/Zn).
